(19) United States
(12) Patent Application Publication
(10) Pub. No.: US 2024/0243017 A1
(43) Pub. Date: Jul. 18, 2024

(54) MEASURING METHOD AND MEASURING DEVICE

(71) Applicant: Japan Display Inc., Tokyo (JP)

(72) Inventors: Satoru TOMITA, Tokyo (JP); Noriyuki HIRATA, Tokyo (JP)

(73) Assignee: Japan Display Inc., Tokyo (JP)

(21) Appl. No.: 18/391,670

(22) Filed: Dec. 21, 2023

(30) Foreign Application Priority Data
Jan. 12, 2023 (JP) 2023-003088

(51) Int. Cl. H01L 21/66; G06T 7/00; G06T 7/60; H10K 59/12

(52) U.S. Cl. CPC H01L 22/12; G06T 7/0004; G06T 7/60; H10K 59/1201; H10K 59/122

(57) ABSTRACT

According to one embodiment, a measuring method includes forming a partition including a lower portion provided on a base and an upper portion which protrudes from a side surface of the lower portion, acquiring a first image generated by applying an electron beam to the partition for each of elements constituting the partition, analyzing the first image for each element, and measuring a protrusion amount of an end portion of the upper portion from the side surface of the lower portion based on the analysis result.

### CROSS-REFERENCE TO RELATED APPLICATIONS

This application is based upon and claims the benefit of priority from Japanese Patent Application No. 2023-003088, filed Jan. 12, 2023, the entire contents of which are incorporated herein by reference.

### FIELD

Embodiments described herein relate generally to a measuring method and a measuring device.

### BACKGROUND

Recently, display devices to which an organic light emitting diode (OLED) is applied as a display element have been put into practical use.

Each of the display devices described above is manufactured by preparing a motherboard in which a plurality of display panels are formed and using each of the display panels cut from the motherboard.

In the process of manufacturing such a display device, a technique which prevents the reduction in the reliability of the display device is required.

### BRIEF DESCRIPTION OF THE DRAWINGS

FIG. 1 is a diagram showing a configuration example of a display device according to an embodiment.

FIG. 2 is a diagram showing an example of the layout of subpixels.

FIG. 3 is a schematic cross-sectional view of the display device along the III-III line of FIG. 2.

FIG. 4 is a schematic cross-sectional view of a partition.

FIG. 5 is a schematic cross-sectional view for explaining a display element formed by using the partition.

FIG. 6 is a schematic cross-sectional view for explaining the display element formed by using the partition.

FIG. 7 is a schematic cross-sectional view for explaining the display element formed by using the partition.

FIG. 8 is a diagram for explaining a motherboard inspection device used in the manufacturing process of the display device.

FIG. 9 is a diagram for explaining the configuration of an EDX device.

FIG. 10 is a diagram showing an example of the hardware configuration of a measuring device.

FIG. 11 is a diagram showing an example of the functional configuration of the measuring device.

FIG. 12 is a flowchart showing an example of the processing procedure of the measuring device.

FIG. 13 is a diagram showing an example of an image of aluminum.

FIG. 14 is a diagram showing an example of an image of titanium.

FIG. 15 is a diagram in which part of the image of aluminum overlaps part of the image of titanium.

FIG. 16 is a diagram showing an example of an image of silicon.

### DETAILED DESCRIPTION

In general, according to one embodiment, a measuring method includes forming a partition including a lower portion provided on a base and an upper portion which protrudes from a side surface of the lower portion, acquiring a first image generated by applying an electron beam to the partition for each of elements constituting the partition, analyzing the first image for each element, and measuring a protrusion amount of an end portion of the upper portion from the side surface of the lower portion based on the analysis result.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as direction X. A direction parallel to the Y-axis is referred to as direction Y. A direction parallel to the Z-axis is referred to as direction Z. When various elements are viewed parallel to direction Z, the appearance is defined as a plan view.

The display device of the present embodiment is an organic electroluminescent display device including an organic light emitting diode (OLED) as a display element, and could be mounted on a television, a personal computer, a vehicle-mounted device, a tablet, a smartphone, a mobile phone, etc.

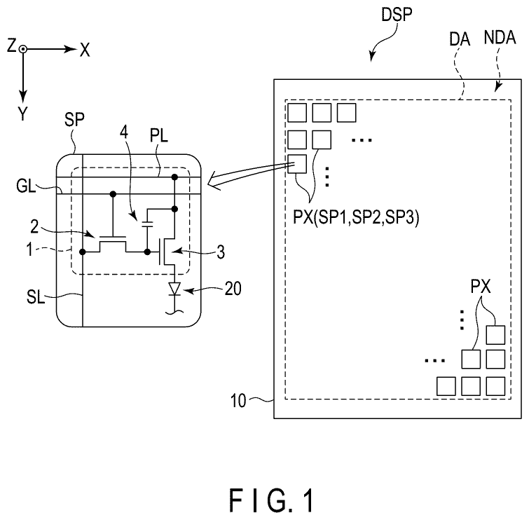

FIG. 1 is a diagram showing a configuration example of a display device DSP according to an embodiment. The display device DSP includes a display area DA which displays an image and a non-display area NDA around the display area DA on an insulating base 10. The base 10 may be glass or a resinous film having flexibility.

In the embodiment, the base 10 is rectangular as seen in plan view. It should be noted that the shape of the base 10 in plan view is not limited to a rectangle and may be another shape such as a square, a circle or an oval.

The display area DA includes a plurality of pixels PX arrayed in matrix in direction X and direction Y. Each pixel PX includes a plurality of subpixels SP. For example, each pixel PX includes a red subpixel SP1, a green subpixel SP2 and a blue subpixel SP3. Each pixel PX may include a subpixel SP which exhibits another color such as white in addition to subpixels SP1, SP2 and SP3. Each pixel PX may include a subpixel SP which exhibits another color instead of one of subpixels SP1, SP2 and SP3.

Each subpixel SP includes a pixel circuit 1 and a display element 20 driven by the pixel circuit 1. The pixel circuit 1 includes a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the display element 20.

It should be noted that the configuration of the pixel circuit 1 is not limited to the example shown in FIG. 1. For example, the pixel circuit 1 may include more thin-film transistors and capacitors.

The display element 20 is an organic light emitting diode (OLED) as a light emitting element. For example, subpixel SP1 includes a display element 20 which emits light in a red wavelength range. Subpixel SP2 includes a display element 20 which emits light in a green wavelength range. Subpixel SP3 includes a display element 20 which emits light in a blue wavelength range.

It should be noted that FIG. 1 shows a display panel mainly used for the manufacture of the display device DSP. The display device DSP includes a structure in which a circuit substrate including a driver (driver IC chip) which drives the display panel, etc., is connected to the display panel.

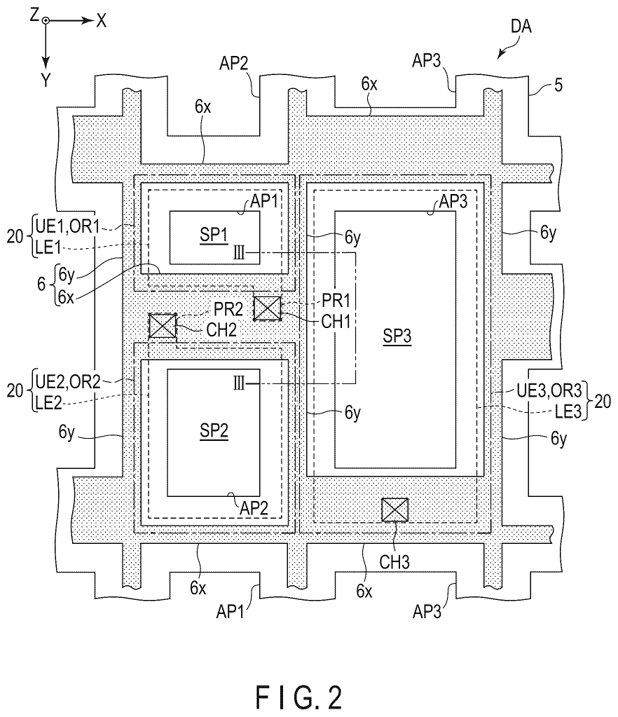

FIG. 2 shows an example of the layout of subpixels SP1, SP2 and SP3. In the example shown in FIG. 2, subpixels SP1 and SP2 are arranged in direction Y. Further, each of subpixels SP1 and SP2 is adjacent to subpixel SP3 in direction X.

When subpixels SP1, SP2 and SP3 are provided in line with the layout shown in FIG. 2, in the display area DA, a column in which subpixels SP1 and SP2 are alternately provided in direction Y and a column in which a plurality of subpixels SP3 are repeatedly provided in direction Y are formed. These columns are alternately arranged in direction X.

It should be noted that the layout of subpixels SP1, SP2 and SP3 is not limited to the example shown in FIG. 2. As another example, subpixels SP1, SP2 and SP3 in each pixel PX may be arranged in order in direction X.

A rib 5 and a partition 6 are provided in the display area DA. The rib 5 includes apertures AP1, AP2 and AP3 in subpixels SP1, SP2 and SP3, respectively. In the example shown in FIG. 2, the aperture AP2 is larger than the aperture AP1, and the aperture AP3 is larger than the aperture AP2. The partition 6 is provided in the boundary between adjacent subpixels SP and overlaps the rib 5 as seen in plan view.

The partition 6 includes a plurality of first partitions 6x extending in direction X and a plurality of second partitions 6y extending in direction Y. The first partitions 6x are provided between the apertures AP1 and AP2 which are adjacent to each other in direction Y and between two apertures AP3 which are adjacent to each other in direction Y. Each second partition 6y is provided between the apertures AP1 and AP3 which are adjacent to each other in direction X and between the apertures AP2 and AP3 which are adjacent to each other in direction X.

In the example shown in FIG. 2, the first partitions 6x and the second partitions 6y are connected to each other. In this configuration, the partition 6 has a grating shape surrounding the apertures AP1, AP2 and AP3 as a whole. In other words, the partition 6 includes apertures in subpixels SP1, SP2 and SP3 in a manner similar to that of the rib 5.

Thus, in the embodiment, the rib 5 and the partition 6 are provided so as to define subpixels SP1, SP2 and SP3.

Subpixel SP1 includes a lower electrode LE1, an upper electrode UE1 and an organic layer OR1 overlapping the aperture AP1. Subpixel SP2 includes a lower electrode LE2, an upper electrode UE2 and an organic layer OR2 overlapping the aperture AP2. Subpixel SP3 includes a lower electrode LE3, an upper electrode UE3 and an organic layer OR3 overlapping the aperture AP3. In the example shown in FIG. 2, the outer shapes of the upper electrode UE1 and the organic layer OR1 are coincident with each other. The outer shapes of the upper electrode UE2 and the organic layer OR2 are coincident with each other. The outer shapes of the upper electrode UE3 and the organic layer OR3 are coincident with each other.

The lower electrode LE1, the upper electrode UE1 and the organic layer OR1 constitute the display element 20 of subpixel SP1. The lower electrode LE2, the upper electrode UE2 and the organic layer OR2 constitute the display element 20 of subpixel SP2. The lower electrode LE3, the upper electrode UE3 and the organic layer OR3 constitute the display element 20 of subpixel SP3.

The lower electrode LE1 is connected to the pixel circuit 1 which drives subpixel SP1 (specifically, the display element 20 of subpixel SP1) through a contact hole CH1. The lower electrode LE2 is connected to the pixel circuit 1 which drives subpixel SP2 (specifically, the display element 20 of subpixel SP2) through a contact hole CH2. The lower electrode LE3 is connected to the pixel circuit 1 which drives subpixel SP3 (specifically, the display element 20 of subpixel SP3) through a contact hole CH3.

In the example shown in FIG. 2, the contact holes CH1 and CH2 entirely overlap the first partition 6x between the apertures AP1 and AP2 which are adjacent to each other in direction Y. The contact hole CH3 entirely overlaps the first partition 6x between two apertures AP3 which are adjacent to each other in direction Y. As another example, at least part of the contact hole CH1, CH2 or CH3 may not overlap the first partition 6x.

In the example shown in FIG. 2, the lower electrodes LE1 and LE2 include protrusions PR1 and PR2, respectively. The protrusion PR1 protrudes from the body of the lower electrode LE1 (the portion overlapping the aperture AP1) toward the contact hole CH1. The protrusion PR2 protrudes from the body of the lower electrode LE2 (the portion overlapping the aperture AP2) toward the contact hole CH2. The contact holes CH1 and CH2 overlap the protrusions PR1 and PR2, respectively.

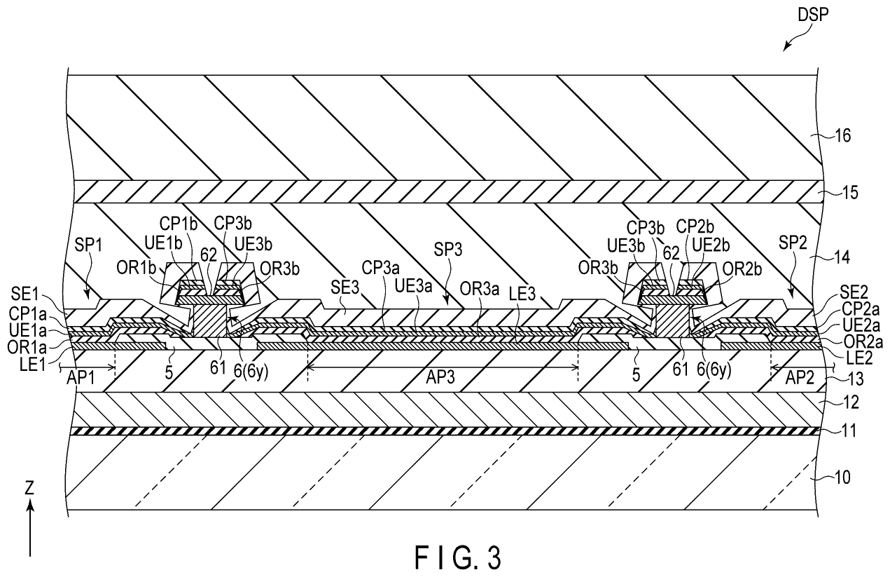

FIG. 3 is a schematic cross-sectional view of the display device DSP along the III-III line of FIG. 2. In the display device DSP, an insulating layer 11 which is called an undercoat layer is provided on the base 10 (specifically, on the surface on which the display element 20 and the like are provided).

The insulating layer 11 includes, for example, a three-layer stacked structure consisting of a silicon oxide film (SiO), a silicon nitride film (SiN) and a silicon oxide film (SiO). It should be noted that the insulating layer 11 is not limited to a three-layer stacked structure and may include a stacked structure consisting of more than three layers or may include a single-layer structure or two-layer stacked structure.

A circuit layer 12 is provided on the insulating layer 11. The circuit layer 12 includes various circuits and lines for driving subpixels SP (SP1, SP2 and SP3), such as the pixel circuit 1, scanning line GL, signal line SL and power line PL shown in FIG. 1. The circuit layer 12 is covered with an insulating layer 13.

The insulating layer 13 functions as a planarization film which planarizes the irregularities formed by the circuit layer 12. Although not shown in FIG. 3, the contact holes CH1, CH2 and CH3 described above are provided in the insulating layer 13.

The lower electrodes LE (LE1, LE2 and LE3) are provided on the insulating layer 13. The rib 5 is provided on the insulating layer 13 and the lower electrodes LE. An end portion (part) of each lower electrode LE is covered with the rib 5.

The partition 6 includes a lower portion 61 provided on the rib 5 and an upper portion 62 which covers the upper surface of the lower portion 61. The upper portion 62 has a width greater than that of the lower portion 61 in direction X and direction Y. By this configuration, the partition 6 has a shape in which the both end portions of the upper portion 62 protrude relative to the side surfaces of the lower portion 61. This shape of the partition 6 may be called an overhang shape.

The organic layers OR (OR1, OR2 and OR3) and the upper electrodes UE (UE1, UE2 and UE3) constitute the display elements 20 with the lower electrodes LE (LE1, LE2 and LE3). As shown in FIG. 3, the organic layer OR1 includes first and second organic layers OR1a and OR1b spaced apart from each other. The upper electrode UE1 includes first and second upper electrodes UE1a and UE1b spaced apart from each other. The first organic layer OR1a is in contact with the lower electrode LE1 through the aperture AP1 and covers part of the rib 5. The second organic layer OR1b is located on the upper portion 62. The first upper electrode UE1a faces the lower electrode LE1 and covers the first organic layer OR1a. Further, the first upper electrode UE1a is in contact with a side surface of the lower portion 61. The second upper electrode UE1b is located above the partition 6 and covers the second organic layer OR1b.

As shown in FIG. 3, the organic layer OR2 includes first and second organic layers OR2a and OR2b spaced apart from each other. The upper electrode UE2 includes first and second upper electrodes UE2a and UE2b spaced apart from each other. The first organic layer OR2a is in contact with the lower electrode LE2 through the aperture AP2 and covers part of the rib 5. The second organic layer OR2b is located on the upper portion 62. The first upper electrode UE2a faces the lower electrode LE2 and covers the first organic layer OR2a. Further, the first upper electrode UE2a is in contact with a side surface of the lower portion 61. The second upper electrode UE2b is located above the partition 6 and covers the second organic layer OR2b.

As shown in FIG. 3, the organic layer OR3 includes first and second organic layers OR3a and OR3b spaced apart from each other. The upper electrode UE3 includes first and second upper electrodes UE3a and UE3b spaced apart from each other. The first organic layer OR3a is in contact with the lower electrode LE3 through the aperture AP3 and covers part of the rib 5. The second organic layer OR3b is located on the upper portion 62. The first upper electrode UE3a faces the lower electrode LE3 and covers the first organic layer OR3a. Further, the first upper electrode UE3a is in contact with a side surface of the lower portion 61. The second upper electrode UE3b is located above the partition 6 and covers the second organic layer OR3b.

In the example shown in FIG. 3, subpixels SP1, SP2 and SP3 include cap layers CP1, CP2 and CP3 for adjusting the optical properties of the light emitted from the light emitting layers of the organic layers OR1, OR2 and OR3, respectively.

The cap layer CP1 includes first and second cap layers CP1a and CP1b spaced apart from each other. The first cap layer CP1a is located in the aperture AP1 and is provided on the first upper electrode UE1a. The second cap layer CP1b is located above the partition 6 and is provided on the second upper electrode UE1b.

The cap layer CP2 includes first and second cap layers CP2a and CP2b spaced apart from each other. The first cap layer CP2a is located in the aperture AP2 and is provided on the first upper electrode UE2a. The second cap layer CP2b is located above the partition 6 and is provided on the second upper electrode UE2b.

The cap layer CP3 includes first and second cap layers CP3a and CP3b spaced apart from each other. The first cap layer CP3a is located in the aperture AP3 and is provided on the first upper electrode UE3a. The second cap layer CP3b is located above the partition 6 and is provided on the second upper electrode UE3b.

Sealing layers SE1, SE2 and SE3 are provided in subpixels SP1, SP2 and SP3, respectively. The sealing layer SE1 continuously covers the members of subpixel SP1 including the first cap layer CP1a, the partition 6 and the second cap layer CP1b. The sealing layer SE2 continuously covers the members of subpixel SP2 including the first cap layer CP2a, the partition 6 and the second cap layer CP2b. The sealing layer SE3 continuously covers the members of subpixel SP3 including the first cap layer CP3a, the partition 6 and the second cap layer CP3b.

In the example shown in FIG. 3, the second organic layer OR1b, the second upper electrode UE1b, the second cap layer CP1b and the sealing layer SE1 on the partition 6 between subpixels SP1 and SP3 are spaced apart from the second organic layer OR3b, the second upper electrode UE3b, the second cap layer CP3b and the sealing layer SE3 on this partition 6. The second organic layer OR2b, the second upper electrode UE2b, the second cap layer CP2b and the sealing layer SE2 on the partition 6 between subpixels SP2 and SP3 are spaced apart from the second organic layer OR3b, the second upper electrode UE3b, the second cap layer CP3b and the sealing layer SE3 on this partition 6.

The sealing layers SE1, SE2 and SE3 are covered with a resin layer 14. The resin layer 14 is covered with a sealing layer 15. Further, the sealing layer 15 is covered with a resin layer 16.

The insulating layer 13 and the resin layers 14 and 16 are formed of organic materials. Each of the rib 5 and the sealing layers 15 and SE (SE1, SE2 and SE3) is formed of, for example, an inorganic material such as silicon nitride (SiNx).

The lower portion 61 of the partition 6 is conductive. The upper portion 62 of the partition 6 may be also conductive. Each lower electrode LE may be formed of a transparent conductive oxide such as indium tin oxide (ITO) or may include a multilayer structure of a metal material such as silver (Ag) and a conductive oxide. Each upper electrode UE is formed of, for example, a metal material such as an alloy of magnesium and silver (MgAg). Each upper electrode UE may be formed of a conductive oxide such as ITO.

When the potential of the lower electrodes LE is relatively higher than that of the upper electrodes UE, the lower electrodes LE correspond to anodes, and the upper electrodes UE correspond to cathodes. When the potential of the upper electrodes UE is relatively higher than that of the lower electrodes LE, the upper electrodes UE correspond to anodes, and the lower electrodes LE correspond to cathodes.

Each organic layer OR includes a pair of functional layers and a light emitting layer provided between these functional layers. For example, each organic layer OR includes a structure in which a hole injection layer, a hole transport layer, an electron blocking layer, a light emitting layer, a hole blocking layer, an electron transport layer and an electron injection layer are stacked in order.

Each of the cap layers CP (CP1, CP2 and CP3) is formed of, for example, a multilayer body of a plurality of transparent thin films. As the thin films, the multilayer body may include a thin film formed of an inorganic material and a thin film formed of an organic material. These thin films have refractive indices different from each other. The materials of the thin films constituting the multilayer body are different from the materials of the upper electrodes UE and are also different from the materials of the sealing layers SE. It should be noted that the cap layers CP may be omitted.

Common voltage is applied to the partition 6. This common voltage is applied to each of the upper electrodes UE (the first upper electrodes UE1a, UE2a and UE3a) which are in contact with the side surfaces of the lower portions 61. Pixel voltage is applied to the lower electrodes LE (LE1, LE2 and LE3) through the pixel circuits 1 provided in subpixels SP (SP1, SP2 and SP3), respectively.

When a potential difference is formed between the lower electrode LE1 and the upper electrode UE1, the light emitting layer of the first organic layer OR1a emits light in a red wavelength range. When a potential difference is formed between the lower electrode LE2 and the upper electrode UE2, the light emitting layer of the first organic layer OR2a emits light in a green wavelength range. When a potential difference is formed between the lower electrode LE3 and the upper electrode UE3, the light emitting layer of the first organic layer OR3a emits light in a blue wavelength range.

As another example, the light emitting layers of the organic layers OR1, OR2 and OR3 may emit light exhibiting the same color (for example, white). In this case, the display device DSP may include color filters which convert the light emitted from the light emitting layers into light exhibiting colors corresponding to subpixels SP1, SP2 and SP3. The display device DSP may include a layer including quantum dots which generate light exhibiting colors corresponding to subpixels SP1, SP2 and SP3 by the excitation caused by the light emitted from the light emitting layers.

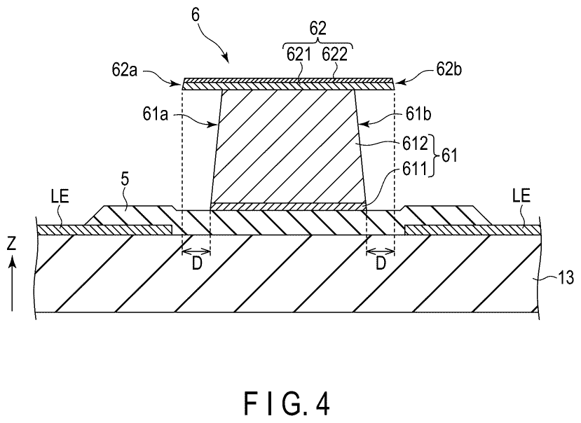

FIG. 4 is a schematic enlarged cross-sectional view of the partition 6. In FIG. 4, the elements other than the rib 5, the partition 6, the insulating layer 13 and a pair of lower electrodes LE are omitted. Each of the pair of lower electrodes LE corresponds to one of the lower electrodes LE1, LE2 and LE3 described above. The first and second partitions 6x and 6y described above include the same structure as the partition 6 shown in FIG. 4.

In the example shown in FIG. 4, the lower portion 61 of the partition 6 includes a barrier layer 611 provided on the rib 5, and a metal layer 612 provided on the barrier layer 611. The barrier layer 611 is formed of a material which is different from that of the metal layer 612, and is formed of, for example, a metal material such as molybdenum. The metal layer 612 is formed so as to be thicker than the barrier layer 611. The metal layer 612 may include either a single-layer structure or a multilayer structure of different metal materials. For example, the metal layer 612 is formed of aluminum (Al).

The upper portion 62 is thinner than the lower portion 61. In the example shown in FIG. 4, the upper portion 62 includes a first layer 621 provided on the metal layer 612, and a second layer 622 provided on the first layer 621. For example, the first layer 621 is formed of titanium (Ti), and the second layer 622 is formed of ITO. Here, this specification explains that the upper portion 62 includes a two-layer stacked structure. However, the upper portion 62 may include a single-layer structure formed of, for example, a metal material such as titanium. The upper portion 62 may be formed of a material other than metal materials and may be formed of an inorganic material such as silicon oxide (SiO). Further, the upper portion 62 may include a stacked layer structure consisting of an appropriate combination of the above materials, specifically, a conductive oxide such as ITO, a metal material such as titanium and an inorganic material such as silicon oxide, or may include a single-layer structure formed of one of the materials described above.

In the example shown in FIG. 4, the width of the lower portion 61 decreases toward the upper portion 62. In other words, the side surfaces 61a and 61b of the lower portion 61 incline with respect to direction Z. The upper portion 62 includes an end portion 62a protruding from the side surface 61a and an end portion 62b protruding from the side surface 61b.

The amount D of protrusion of each of the end portions 62a and 62b from the side surfaces 61a and 61b (hereinafter, referred to as the protrusion amount D of the partition 6) is, for example, less than or equal to 2.0 μm. In the embodiment, the protrusion amount D of the partition 6 corresponds to the length (distance) of the partition 6 between the lower ends of the side surfaces 61a and 61b (barrier layer 611) and the end portions 62a and 62b in a width direction (direction X or direction Y) orthogonal to direction Z. The protrusion amount D of the partition 6 may be the length of the partition 6 between the upper ends of the side surfaces 61a and 61b and the end portions 62a and 62b in a width direction orthogonal to direction Z.

The structure of the partition 6 and the materials of the elements of the partition 6 may be appropriately selected in consideration of, for example, the method for forming the partition 6.

Here, in the embodiment, the partition 6 is formed so as to define subpixels SP as seen in plan view. The organic layers OR described above are formed by, for example, a vacuum deposition method having anisotropy or directionality. When the organic material for forming each organic layer OR is deposited on the entire base 10 in a state where the partition 6 is provided, the organic layers OR are not substantially formed on the side surfaces of the partition 6 as the partition 6 has the shape shown in FIG. 3 and FIG. 4. By this configuration, the organic layers OR (display elements 20) divided for each subpixel SP by the partition 6 can be formed.

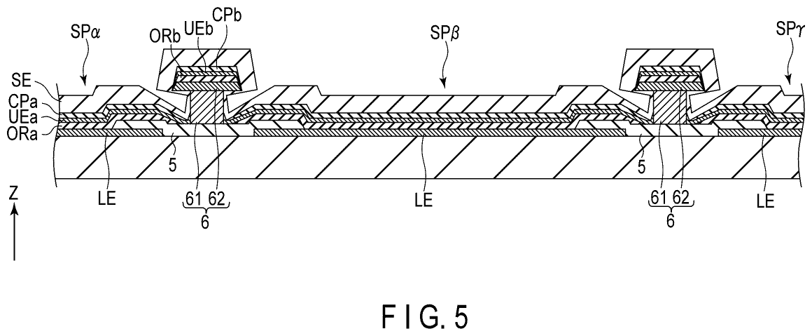

Each of FIG. 5 to FIG. 7 is a schematic cross-sectional view for explaining the display element 20 which is formed using the partition 6. Each of subpixels SPα, SPβ and SPγ shown in FIG. 5 to FIG. 7 corresponds to one of subpixels SP1, SP2 and SP3.

An organic layer OR, an upper electrode UE, a cap layer CP and a sealing layer SE are formed in order by vapor deposition over the entire base 10 as shown in FIG. 5 in a state where the partition 6 is provided as described above. The organic layer OR includes a light emitting layer which emits light exhibiting a color corresponding to subpixel SPα. The partition 6 having an overhang shape divides the organic layer OR into a first organic layer ORa which covers a lower electrode LE and a second organic layer ORb on the partition 6, and divides the upper electrode UE into a first upper electrode UEa which covers the first organic layer ORa and a second upper electrode UEb which covers the second organic layer ORb, and divides the cap layer CP into a first cap layer CPa which covers the first upper electrode UEa and a second cap layer CPb which covers the second upper electrode UEb. The first upper electrode UEa is in contact with the lower portion 61 of the partition 6. The sealing layer SE continuously covers the first cap layer CPa, the second cap layer CPb and the partition 6.

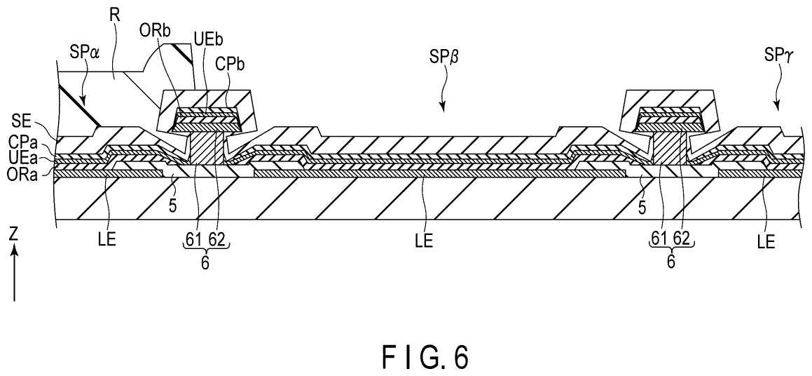

Subsequently, as shown in FIG. 6, a resist R is formed on the sealing layer SE. The resist R covers subpixel SPα. In other words, the resist R is provided immediately above the first organic layer ORa, the first upper electrode UEa and the first cap layer CPa located in subpixel SPα. The resist R is also located immediately above, of the second organic layer ORb, the second upper electrode UEb and the second cap layer CPb on the partition 6 between subpixels SPα and SPβ, the portion close to subpixel SPα. In other words, at least part of the partition 6 is exposed from the resist R.

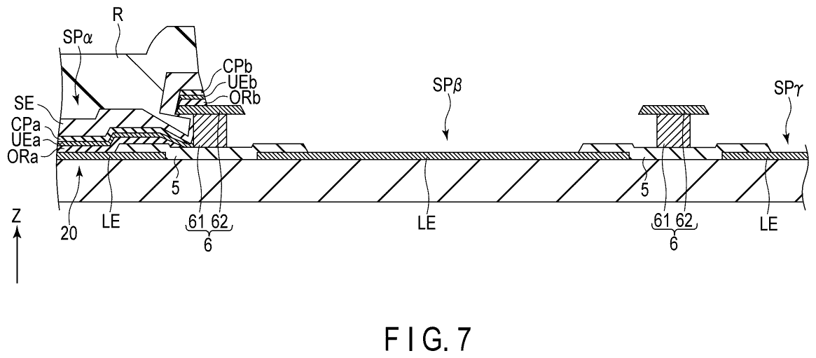

Further, the portion exposed from the resist R is removed from the organic layer OR, the upper electrode UE, the cap layer CP and the sealing layer SE as shown in FIG. 7 by etching using the resist R as a mask. In this way, the display element 20 including the lower electrode LE, the first organic layer ORa, the first upper electrode UEa and the first cap layer CPa is formed in subpixel SPα. In subpixels SPβ and SPγ, the lower electrode LE is exposed. The etching described above includes, for example, dry etching for the sealing layer SE, wet etching and dry etching for the cap layer CP, wet etching for the upper electrode UE and dry etching for the organic layer OR.

When the display element 20 of subpixel SPα is formed as described above, the resist R is removed, and the display elements 20 of subpixels SPβ and SPγ are formed in series in a manner similar to that of subpixel SPα.

The structure of the display device DSP shown in FIG. 3 is realized by forming the display elements 20 of subpixels SP1, SP2 and SP3 as exemplarily shown above regarding subpixels SPα, SPβ and SPγ and further forming the resin layer 14, the sealing layer 15 and the resin layer 16.

Here, as described above, the partition 6 includes the lower portion 61 and the upper portion 62 which protrudes from the side surfaces of the lower portion 61. When the protrusion amount D (eave width) of the partition 6 is not appropriate, there is a possibility that the reliability of the display device DSP is decreased.

Specifically, the display device DSP is configured such that the organic layer OR is divided for each subpixel SP by the partition 6. When the protrusion amount D of the partition 6 is not sufficiently greater than the designed value, there is a possibility that the organic layer OR cannot be appropriately divided. Further, when the side surfaces of the lower portion 61 of the partition 6 are covered with the organic layer OR, electric connection between the lower portion 61 and the upper electrode UE is interrupted. The upper electrode UE is in contact with a side surface of the lower portion 61 of the partition 6 in the display device DSP. However, when the protrusion amount D of the partition 6 exceeds the designed value, there is a possibility that the upper electrode UE does not come into contact with the side surface of the lower portion 61.

Thus, when the protrusion amount D of the partition 6 described above is not appropriate, a display device DSP with high reliability cannot be manufactured. Therefore, measurement of the protrusion amount D (that is, the length between the side surface of the lower portion 61 of the partition 6 and the end portion of the upper portion 62) is useful in the manufacturing process of the display device DSP.

In general, display devices DSP are manufactured by manufacturing a motherboard in which a plurality of display panels are formed on a mother base including a plurality of bases 10 and using the display panels each cut from the motherboard in the manufacturing process of the display devices DSP.

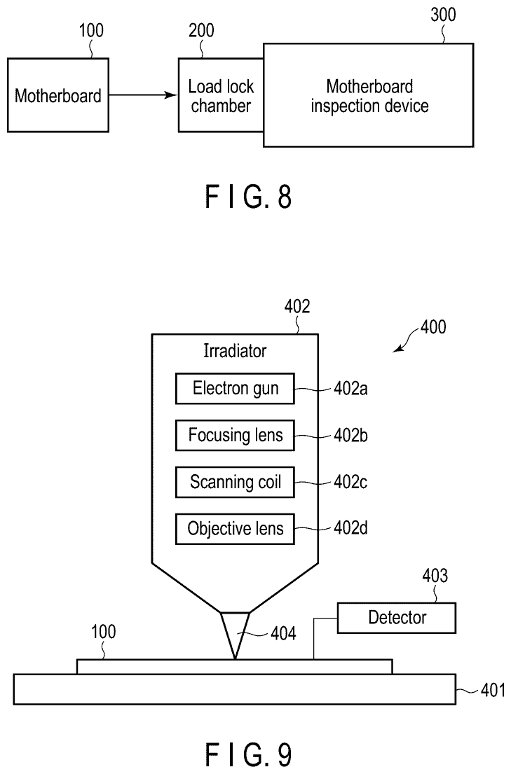

In the manufacturing process of the display devices DSP described above, as shown in FIG. 8, a motherboard (array substrate) 100 is inserted into a motherboard inspection device 300 in which a vacuum state is maintained via a load lock chamber 200, and the quality of the motherboard 100 is inspected in the motherboard inspection device 300.

In this case, for example, a scanning electron microscopy (SEM) is mounted on the motherboard inspection device 300. The motherboard inspection device 300 can perform a component (element) analysis relative to the motherboard 100 by using an energy dispersive X-ray spectroscopy (EDX) device attached to the SEM.

The present embodiment considers measuring (inspecting) the protrusion amount D of the partition 6 in flux continuously by using the EDX device described above.

Here, the configuration of the EDX device described above is briefly explained with reference to FIG. 9. As shown in FIG. 9, an EDX device 400 includes a sample stand 401, an irradiator (emission unit) 402 and a detector 403. The irradiator 402 includes an electron gun 402a, a focusing lens 402b, a scanning coil 402c and an objective lens 402d.

The electron gun 402a generates electron beams. The focusing lens 402b and the objective lens 402d focus electron beams to an electron spot on the sample (here, the motherboard 100) placed on the sample stand 401. By this configuration, the irradiator 402 can irradiate the sample with an electron beam 404. The scanning coil 402c scans (moves) the electron spot to which electron beams are focused (that is, the irradiation point of the electron beam 404) on the sample.

Here, the electron beam 404 applied from the irradiator 402 to the sample as described above gets into a predetermined depth from the surface of the sample and generates characteristic X-rays corresponding to the elements constituting the sample. These characteristic X-rays are detected by the detector 403.

The EDX device 400 performs an element analysis (contained element component analysis) using the characteristic X-rays generated from the irradiation points of the electron beam 404 with which the sample has been scanned, and specifies the elements constituting the sample. The EDX device 400 can generate an image (EDX image) based on the specified elements constituting the sample. It should be noted that the EDX image corresponds to an image in which images for the respective elements constituting the sample overlap each other.

In the embodiment, it is assumed that the protrusion amount D of the partition 6 is measured by using an EDX image generated by the EDX device as described above.

In the embodiment, the protrusion amount D of the partition 6 is assumed to be measured by a measuring device communicably connected to the EDX device 400. It should be noted that the measuring device may be realized as part of the motherboard inspection device 300 or may be realized as a device which is different from the motherboard inspection device 300. The measuring device may be realized as an integral unit with the EDX device 400 described above.

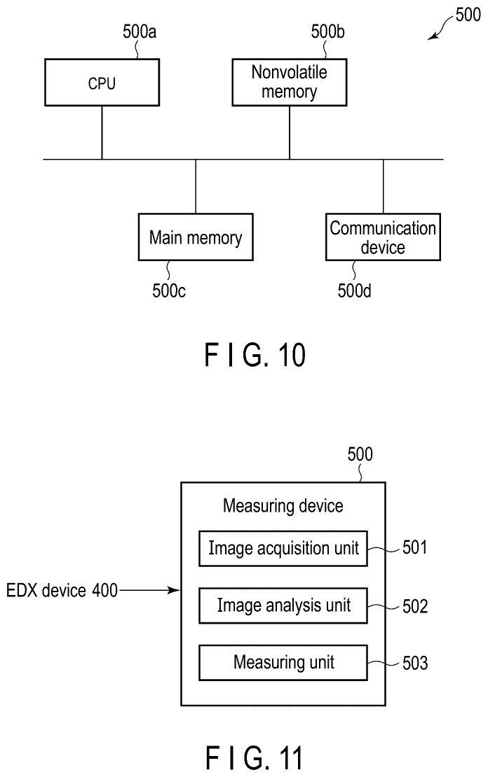

The measuring device of the embodiment is explained below. FIG. 10 shows an example of the hardware configuration of the measuring device.

The measuring device 500 shown in FIG. 10 is realized by, for example, a personal computer, and includes a CPU 500a, a nonvolatile memory 500b, a main memory 500c, a communication device 500d, etc.

The CPU 500a is a processor for controlling the operation of the measuring device 500 and executes various types of programs loaded from the nonvolatile memory 500b into the main memory 500c. The communication device 500d performs communication with an external device (for example, the EDX device 400) of the measuring device 500.

FIG. 11 shows an example of the functional configuration of the measuring device 500. As shown in FIG. 11, the measuring device 500 includes an image acquisition unit 501, an image analysis unit 502 and a measuring unit 503.

The units 501 to 503 included in the measuring device 500 are functional units which are realized when, for example, the CPU 500a described above (that is, the computer of the measuring device 500) executes predetermined programs (in other words, software). However, part of or all of these units 501 to 503 may be realized by hardware such as an integrated circuit (IC) or may be realized by a combination of software and hardware.

In the embodiment, the measuring device 500 is communicably connected to the EDX device 400. The image acquisition unit 501 acquires an EDX image generated by the EDX device 400 as described above from the EDX device 400. The image analysis unit 502 analyzes the EDX image acquired by the image acquisition unit 501. The measuring unit 503 measures the protrusion amount D of the partition 6 formed on the motherboard 100 described above (that is, the length from the side surface of the lower portion 61 of the partition 6 to the end portion of the upper portion 62) based on the analysis result by the image analysis unit 502.

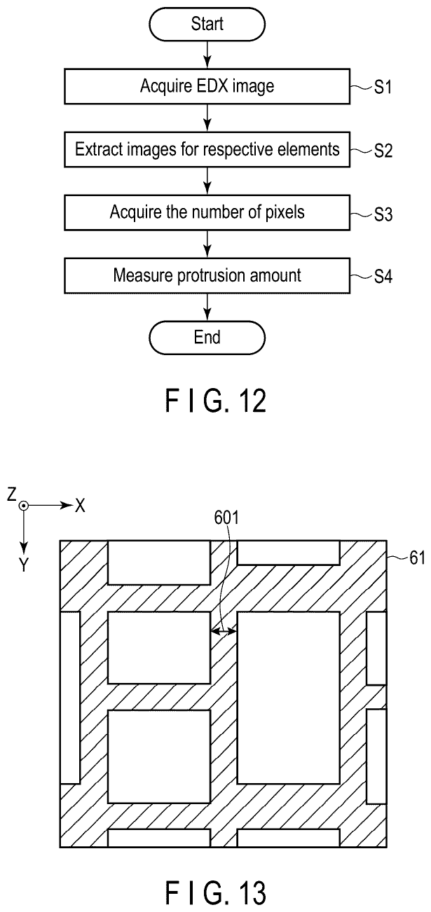

Now, this specification explains an example of the processing procedure of the measuring device 500 of the embodiment with reference to the flowchart of FIG. 12.

First, when the motherboard 100 in which the insulating layer 11, the circuit layer 12, the insulating layer 13, the lower electrodes LE, the rib 5 and the partition 6 are formed on a mother base including a plurality of bases 10 is manufactured, the motherboard 100 is inserted into the motherboard inspection device 300 via the load lock chamber 200 shown in FIG. 8. In the motherboard inspection device 300, the EDX device 400 generates an EDX image and outputs the EDX image to the measuring device 500.

It should be noted that the EDX image output from the EDX device 400 to the measuring device 500 corresponds to an image prepared by overlapping images generated for the respective elements constituting the motherboard 100 based on the result of the analysis of the elements by applying the electron beam 404 to the motherboard 100 (specifically, the partition 6, etc., formed on the motherboard 100). In the embodiment, as an EDX image is used to measure the protrusion amount D of the partition 6, the EDX device 400 applies the electron beam 404 to, of the upper portion 62 of the partition 6, the surface opposite to the base 10 (lower portion 61) in a direction perpendicular to the base 10. The electron beam 404 is assumed to be applied with intensity at least to the extent that it passes through the upper portion 62 of the partition 6 and reaches the lower portion 61.

In the embodiment, an EDX image (image file) is assumed to have, for example, a file format such as jpeg. However, an EDX image may have another file format.

The EDX image output from the EDX device 400 as described above is acquired by the image acquisition unit 501 included in the measuring device 500 (step S1).

Subsequently, the image acquisition unit 501 extracts images for the respective elements which constitute the partition 6 from the EDX image acquired in step S1 (step S2).

Here, the lower portion 61 (metal layer 612) of the partition 6 is formed of, for example, aluminum. The upper portion 62 (first layer 621) of the partition is formed of, for example, titanium. In this case, the image acquisition unit 501 extracts an image of aluminum and an image of titanium from the EDX image acquired in step S1.

In the embodiment, the image of aluminum extracted from the EDX image corresponds to an image which is generated by mapping characteristic X-rays corresponding to the aluminum detected by the detector 403 provided in the EDX device 400 (in other words, characteristic X-rays generated from the aluminum) to pixels. The image of titanium extracted from the EDX image corresponds to an image which is generated by mapping characteristic X-rays corresponding to titanium detected by the detector 403 provided in the EDX device 400 (in other words, characteristic X-rays generated from the titanium) to pixels.

When the process of step S2 is performed, the image analysis unit 502 acquires the number of pixels corresponding to the protrusion amount D of the partition 6 based on the images of the respective elements extracted in step S2 (step S3).

Here, FIG. 13 shows an example of an image of aluminum. In the image of aluminum shown in FIG. 13, the lower portion 61 of the partition 6 formed of aluminum is visualized. For example, the width 601 (in other words, the number of pixels indicating width 601) of the lower portion 61 in direction X in plan view can be recognized from the image of aluminum.

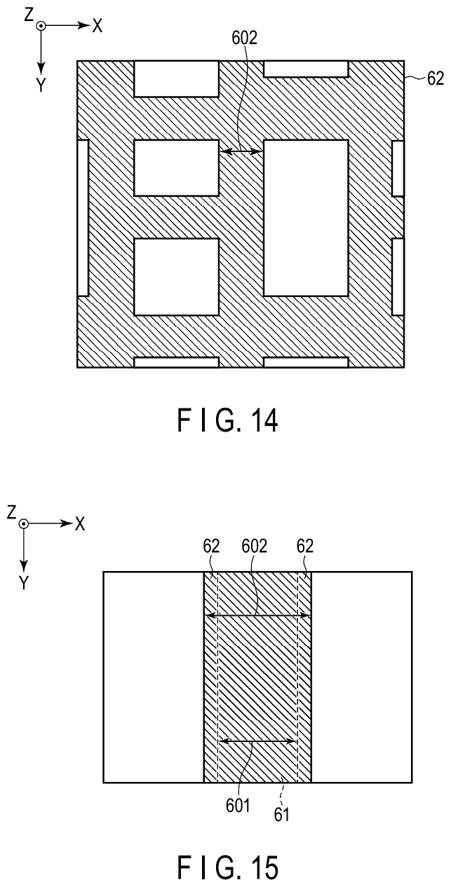

FIG. 14 shows an example of an image of titanium. In the image of titanium shown in FIG. 14, the upper portion 62 of the partition 6 formed of titanium is visualized. For example, the width 602 (in other words, the number of pixels indicating width 602) of the upper portion 62 in direction X in plan view can be recognized from the image of titanium.

In this case, the image analysis unit 502 can acquire the number of pixels corresponding to the protrusion amount D of the partition 6 based on the difference between the width 601 of the lower portion 61 in direction X recognized from the image of aluminum and the width 602 of the upper portion 62 in direction X recognized from the image of titanium.

Here, in FIG. 15, part of the image of aluminum shown in FIG. 13 and part of the image of titanium shown in FIG. 14 overlap each other. According to FIG. 15, the width 602 of the upper portion 62 of the partition 6 is greater than the width 601 of the lower portion 61 of the partition 6, and the number of pixels corresponding to the protrusion amount D of the partition 6 can be acquired from the difference between the width 601 of the lower portion 61 (the number of pixels indicating width 601) and the width 602 of the upper portion 62 (the number of pixels indicating width 602). Specifically, the number of pixels corresponding to the protrusion amount D of the partition 6 can be calculated by, for example, (the number of pixels indicating the width 602 of the upper portion 62−the number of pixels indicating the width 601 of the lower portion 61)×½.

In the above explanation, the number of pixels corresponding to the protrusion amount D of the partition 6 is acquired by calculation using the difference between the width 601 of the lower portion 61 and the width 602 of the upper portion 62. However, the number of pixels corresponding to the protrusion amount D of the partition 6 may be counted on an image in which an image of aluminum and an image of titanium overlap each other as shown in FIG. 15 described above.

Further, in the above explanation, the number of pixels corresponding to the protrusion amount D of the partition 6 is acquired based on the difference between the X-directional width 601 of the lower portion 61 extending in direction Y and the X-directional width 602 of the upper portion 62 extending in direction Y. However, for example, the number of pixels corresponding to the protrusion amount D of the partition 6 may be acquired based on the difference between the Y-directional width of the lower portion 61 extending in direction X and the Y-directional width of the upper portion 62 extending in direction X.

The embodiment is explained assuming that images for respective elements (an image of aluminum and an image of titanium) are extracted from an EDX image, and the number of pixels corresponding to the protrusion amount D of the partition 6 is acquired based on the extracted images for the respective elements. However, for example, when the area in which aluminum is visualized and the area in which titanium is visualized can be specified based on the pixel value (luminance value) of each of the pixels constituting an EDX image, the present embodiment may be configured such that the number of pixels corresponding to the protrusion amount D of the partition 6 is acquired based on the specified area in which aluminum is visualized and the specified area in which titanium is visualized in the EDX image.

Thus, in the embodiment, the number of pixels corresponding to the protrusion amount D of the partition 6 is should be acquired from the feature of an EDX image (images for respective elements) (that is, the analysis result for an EDX image) which can be recognized by analyzing the EDX image.

Subsequently, the measuring unit 503 measures the protrusion amount D of the partition 6 based on the number of pixels acquired in step S3 (step S4).

In step S5, for example, the measuring unit 503 performs a process for converting the number of pixels acquired in step S3 into the protrusion amount D of the partition 6 (the length between the side surface of the lower portion 61 and the end portion of the upper portion 62) based on conversion information prepared in advance.

For example, the conversion information is generated based on an image which is generated by applying an electron beam 404 to a sample whose size (length) has been known and which represents at least one of the elements constituting the sample (that is, a standard sample EDX image including a sample). Specifically, conversion information indicating a length corresponding to a pixel is generated by counting the number of pixels provided between an end of a sample included in a standard sample EDX image (specifically, a pixel corresponding to such an end) and the other end (specifically, a pixel corresponding to the other end) and dividing the known size of the sample by the counted number of pixels. According to this conversion information, when the length which corresponds to a pixel and is indicated by the conversion information is multiplied by the number of pixels acquired in step S3, the number of pixels can be converted into the protrusion amount D (actual size) of the partition 6. It should be noted that the conversion information should be information by which the number of pixels can be converted into the length (in other words, information which defines the correspondence relationship between the number of pixels and the length).

In the above explanation, the protrusion amount D of the partition 6 is measured based on conversion information indicating a length corresponding to a pixel. However, the protrusion amount D of the partition 6 may be measured (calculated) by using a machine learning model generated by machine learning algorithm such as a neural network. This machine learning model should be constructed (generated) so as to output the protrusion amount D (actual size) of the partition 6 by inputting the number of pixels acquired from an EDX image (images for respective elements) and corresponding to the protrusion amount D of the partition 6 by learning a data set prepared in advance (in other words, so as to predict the protrusion amount D of the partition D from the number of pixels). It should be noted that the data set used to generate this machine learning model is assumed to include the number of pixels corresponding to the known protrusion amount D of the partition 6 acquired manually or automatically from images (for example, an image of aluminum and an image of titanium) which are generated by applying an electron beam 404 to the partition 6 whose protrusion amount D has been known and which represent the respective elements constituting the partition 6 and the known protrusion amount D of the partition 6.

When the protrusion amount D of the partition 6 measured by the process shown in FIG. 12 described above is appropriate, the display element 20 of each subpixel SP can be formed as explained with reference to FIG. 5 to FIG. 7 described above in the motherboard 100.

In FIG. 12 described above, the case where the protrusion amount D of part of the partition 6 formed on the motherboard 100 is measured is explained. However, the process shown in FIG. 12 may be performed a plurality of times so as to measure the protrusion amount D in a plurality of portions of the partition 6.

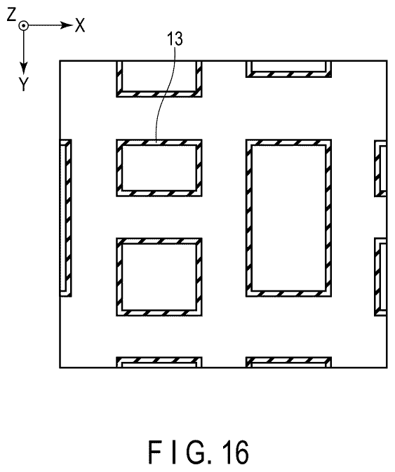

The present embodiment is explained such that the protrusion amount D of the partition 6 is measured by using an image of the element (aluminum) constituting the lower portion 61 of the partition 6 and an image of the element (titanium) constituting the upper portion 62. However, the protrusion amount D of the partition 6 may be measured by using, for example, an image of the element of silicon (Si) constituting the insulating layer 13 (rib 5) shown in FIG. 16. The insulating layer 13 is formed on substantially the whole surface of the motherboard 100. However, in FIG. 16, the silicon formed under the metal materials (Al, Ti, Ag, etc.,) constituting the partition 6 (the lower portion 61 and the upper portion 62) and the lower electrodes LE is not detected. In other words, for example, FIG. 16 shows an image in which the insulating layer 13 formed between the upper portion 62 of the partition 6 and the lower electrodes LE is visualized as seen in plan view.

For example, when the lower portion 61 of the partition 6 is formed with relatively high accuracy, there is a possibility that measurement (prediction) in which the protrusion amount D of the partition 6 is appropriate can be performed in a case where the width (the number of pixels) of the insulating layer 13 formed between the upper portion 62 and the lower electrodes LE in the image shown in FIG. 16 in direction X or direction Y is in a predetermined range.

Thus, in the present embodiment, the protrusion amount D of the partition 6 is measured based on an EDX image (images for respective elements), but the elements (specifically, images) used to measure the protrusion amount D of the partition 6 can be appropriately selected (changed).

As described above, in the embodiment, the partition 6 including the lower portion 61 provided on the base 10 (mother base) and the upper portion 62 protruding from the side surfaces of the lower portion 61 is formed. Images (first images) which are generated by applying an electron beam 404 to the partition 6 and represent the respective elements constituting the partition 6 are acquired. The acquired images for the respective elements are analyzed. Based on the analysis results, the protrusion amount D of the partition 6 (the length from the side surface of the lower portion 61 to the end portion of the upper portion 62) is measured.

Specifically, in the embodiment, an image of the element (for example, aluminum) constituting the lower portion 61 of the partition 6 and an image of the element (for example, titanium) constituting the upper portion 62 are acquired. The number of pixels corresponding to the protrusion amount D of the partition 6 is acquired based on the acquired images. The protrusion amount of the partition 6 is measured based on the acquired number of pixels.

For example, the number of pixels corresponding to the protrusion amount D of the partition 6 is acquired based on the difference between the number of pixels indicating the width of the lower portion 61 formed of aluminum (first element) in plan view and the number of pixels indicating the width of the upper portion 62 formed of titanium (second element) in plan view.

It should be noted that, when the protrusion amount D of the partition 6 is measured based on an image of the element constituting the lower portion 61 and an image of the element constituting the upper portion 62 as described above, an electron beam 404 for generating the images for the respective elements (an EDX image) is assumed to be applied to, of the upper portion 62, the surface opposite to the base 10, in a direction perpendicular to the base 10 with intensity such that the electron beam at least passes through the upper portion 62 and reaches the lower portion 61.

In the embodiment, as the display device DSP can be manufactured by measuring the protrusion amount D of the partition 6 (in other words, by confirming whether or not the protrusion amount D of the partition 6 is appropriate) because of the above configuration, the reduction in the reliability of the display device DSP can be prevented.

In the embodiment, the measuring device 500 is configured to measure the protrusion amount D of the partition 6 by using the EDX device 400 attached to the SEM mounted on the motherboard inspection device 300 used to inspect the quality of the motherboard 100. Thus, measurement (inspection) can be realized in flux continuously using existing facilities.

As described above, in the embodiment, the protrusion amount D of the partition 6 acquired from an EDX image (images for respective elements) should be measured. The protrusion amount D of the partition 6 may be measured by, for example, using conversion information or a machine learning model. In this case, for example, the conversion information may be prepared in advance based on images (second images) which are generated by applying an electron beam 404 to a sample whose size (length) has been known and which represent the respective elements constituting the sample. The machine learning model may be generated by learning a data set including the number of pixels corresponding to the known protrusion amount D of the partition 6 and acquired based on images (second images) which are generated by applying an electron beam 404 to the partition 6 (sample) whose protrusion amount D has been known and which represent the respective elements constituting the partition 6 and the known protrusion amount D of the partition 6.

The embodiment is explained such that the protrusion amount D of the partition 6 is measured based on the number of pixels acquired from an EDX image (images for respective elements) and corresponding to the protrusion amount D of the partition 6. However, a predetermined image process may be performed to acquire the appropriate number of pixels to measure the protrusion amount D of the partition 6. Alternatively, a machine learning model constructed to acquire the appropriate number of pixels from an EDX image may be used.

All measuring methods and measuring devices, which are implementable with arbitrary changes in design by a person of ordinary skill in the art based on the measuring methods and measuring devices described above as the embodiments of the present invention, belong to the scope of the present invention as long as they encompass the spirit of the present invention.

Various modifications are easily conceivable within the category of the idea of the present invention by a person of ordinary skill in the art, and these modifications are also considered to belong to the scope of the present invention. For example, additions, deletions or changes in design of the constituent elements or additions, omissions or changes in condition of the processes may be arbitrarily made to the above embodiments by a person of ordinary skill in the art, and these modifications also fall within the scope of the present invention as long as they encompass the spirit of the present invention.

In addition, the other advantages of the aspects described in the above embodiments, which are obvious from the descriptions of the specification or which are arbitrarily conceivable by a person of ordinary skill in the art, are considered to be achievable by the present invention as a matter of course.

What is claimed is:

1. A measuring method comprising:
forming a partition including a lower portion provided on a base, and an upper portion which protrudes from a side surface of the lower portion;
acquiring a first image generated by applying an electron beam to the partition for each of elements constituting the partition;
analyzing the first image for each element; and
measuring a protrusion amount of an end portion of the upper portion from the side surface of the lower portion based on the analysis result.

2. The measuring method of claim 1, wherein
the acquiring includes acquiring the first image of a first element constituting the lower portion and the first image of a second element constituting the upper portion,
the analyzing includes acquiring a number of pixels corresponding to the protrusion amount based on the first image of the first element and the first image of the second element, and
the measuring includes measuring the protrusion amount based on the number of pixels.

3. The measuring method of claim 2, wherein
the number of pixels corresponding to the protrusion amount is acquired based on a difference between the number of pixels indicating a width of the lower portion formed of the first element in plan view and the number of pixels indicating a width of the upper portion formed of the second element in plan view.

4. The measuring method of claim 2, wherein
the measuring includes converting the number of pixels into the protrusion amount based on conversion information indicating a length corresponding to a pixel, and
the conversion information is prepared in advance based on a second image of at least one of elements constituting a sample whose size has been known, the second image being generated by applying an electron beam to the sample.

5. The measuring method of claim 2, wherein
the measuring includes acquiring the protrusion amount output from a machine learning model by inputting the number of pixels to the machine learning model, the machine learning model being generated by learning a prepared data set, and
the data set includes a number of pixels acquired based on a second image of each of the elements constituting the partition whose protrusion amount has been known, and the known protrusion amount, the second image being generated by applying an electron beam to the partition, the number of pixels being corresponding to the known protrusion amount.

6. The measuring method of claim 1, wherein
the electron beam is applied to, of the upper portion, a surface opposite to the base in a direction perpendicular to the base with intensity such that the electron beam at least passes through the upper portion and reaches the lower portion.

7. A measuring device comprising:
an acquisition unit configured to acquire a first image generated by applying an electron beam to a partition including a lower portion provided on a base and an upper portion which protrudes from a side surface of the lower portion for each of elements constituting the partition;
an analysis unit configured to analyze the first image for each element; and
a measuring unit configured to measure a protrusion amount of an end portion of the upper portion from a side surface of the lower portion based on the analysis result.

8. The measuring device of claim 7, wherein
the acquisition unit is configured to acquire the first image of a first element constituting the lower portion, and the first image of a second element constituting the upper portion,
the analysis unit is configured to acquire a number of pixels corresponding to the protrusion amount based on the first image of the first element and the first image of the second element, and
the measuring unit is configured to measure the protrusion amount based on the number of pixels.

9. The measuring device of claim 8, wherein
the number of pixels corresponding to the protrusion amount is acquired based on a difference between the number of pixels indicating a width of the lower portion formed of the first element in plan view and the number of pixels indicating a width of the upper portion formed of the second element in plan view.

10. The measuring device of claim 8, wherein
the measuring unit is configured to convert the number of pixels into the protrusion amount based on conversion information indicating a length corresponding to a pixel, and
the conversion information is prepared in advance based on a second image of at least one of elements constituting a sample whose size has been known, the second image being generated by applying an electron beam to the sample.

11. The measuring device of claim 8, wherein
the measuring unit is configured to acquire the protrusion amount output from a machine learning model by inputting the number of pixels to the machine learning model, the machine learning model being generated by learning a prepared data set, and
the data set includes a number of pixels acquired based on a second image of each of the elements constituting the partition whose protrusion amount has been known, and the known protrusion amount, the second image being generated by applying an electron beam to the partition, the number of pixels being corresponding to the known protrusion amount.

12. The measuring device of claim 7, wherein
the electron beam is applied to, of the upper portion, a surface opposite to the base in a direction perpendicular to the base with intensity such that the electron beam at least passes through the upper portion and reaches the lower portion.

13. A measuring device comprising:
an irradiator configured to apply an electron beam to a partition including a lower portion provided on a base and an upper portion which protrudes from a side surface of the lower portion;
a detector configured to detect a characteristic X-ray generated from the partition by applying the electron beam;
an acquisition unit configured to acquire a first image generated based on the detected characteristic X-ray for each of elements constituting the partition;
an analysis unit configured to analyze the first image for each element; and
a measuring unit configured to measure a protrusion amount of an end portion of the upper portion from a side surface of the lower portion based on the analysis result.

14. The measuring device of claim 13, wherein
the acquisition unit is configured to acquire the first image of a first element constituting the lower portion and the first image of a second element constituting the upper portion,
the analysis unit is configured to acquire a number of pixels corresponding to the protrusion amount based on the first image of the first element and the first image of the second element, and
the measuring unit is configured to measure the protrusion amount based on the number of pixels.

15. The measuring device of claim 14, wherein
the number of pixels corresponding to the protrusion amount is acquired based on a difference between the number of pixels indicating a width of the lower portion formed of the first element in plan view and the number of pixels indicating a width of the upper portion formed of the second element in plan view.

16. The measuring device of claim 14, wherein
the measuring unit is configured to convert the number of pixels into the protrusion amount based on conversion information indicating a length corresponding to a pixel, and
the conversion information is prepared in advance based on a second image of at least one of elements constituting a sample whose size has been known, the second image being generated by applying an electron beam to the sample.

17. The measuring device of claim 14, wherein
the measuring unit is configured to acquire the protrusion amount output from a machine learning model by inputting the number of pixels to the machine learning model, the machine learning model being generated by learning a prepared data set, and
the data set includes a number of pixels acquired based on a second image of each of the elements constituting the partition whose protrusion amount has been known, and the known protrusion amount, the second image being generated by applying an electron beam to the partition, the number of pixels being corresponding to the known protrusion amount.

18. The measuring device of claim 13, wherein
the electron beam is applied to, of the upper portion, a surface opposite to the base in a direction perpendicular to the base with intensity such that the electron beam at least passes through the upper portion and reaches the lower portion.
